(19) United States
(12) Patent Application Publication
(10) Pub. No.: US 2010/0270566 A1
(43) Pub. Date: Oct. 28, 2010

(54) LIGHT EMITTING DEVICE WITH SELECTIVE REFLECTION FUNCTION

(76) Inventors: Wei-Kang CHENG, Lung Tan (TW); Yi-Sheng Ting, Lung Tan (TW); Shyi-Ming Pan, LungTan (TW)

Correspondence Address: SINORICA, LLC, 2275 Research Blvd., Suite 500, ROCKVILLE, MD, 20850, US

(21) Appl. No.: 12/543,681

(22) Filed: Aug. 19, 2009

(30) Foreign Application Priority Data
Apr. 24, 2009 (TW) 098113710

(51) Int. Cl. H01L 33/00

(52) U.S. Cl. 257/89; 257/E33.059

(57) ABSTRACT

A light emitting device with selective reflection function being applied to general light emitting device and AC-type light emitting device is revealed. The light emitting device includes at least one vertical light emitting unit, at least one selective reflection layer and a phosphor layer. The selective reflection layer is disposed over the vertical light emitting unit and the phosphor layer is arranged over the selective reflection layer. Thus first colored light from the vertical light emitting unit passes the selective reflection layer and then to be converted into second colored light by the phosphor layer. The selective reflection layer reflects the second colored light while the first colored light is mixed with the second colored light to form mixing colored light. By the selective reflection layer that prevents the second colored light emitting into the light emitting unit, the lighting efficiency of the light emitting device is enhanced.

### BACKGROUND OF THE INVENTION

1. Field of Invention

The present invention relates to a light emitting device, especially to a light emitting device with selective reflection function for improving color mixing efficiency.

2. Description of Related Art

Nowadays light emitting diode (LED) technology has become mature. The LED features on good shock resistance, low power consumption, long lifetime and low heat generation. It has become one of the essentials in our daily lives and has been applied to various electrical appliances and worked as indicators or light sources of various kinds of equipments. Moreover, more and more outdoor lighting devices or displays such as traffic signs and outdoor displays use LED as light emitting elements. Now along with the trend of energy saving and carbon reduction, LED has become mainstream as the backlight source of liquid crystal displays because LED provides high brightness with low power consumption.

The LED is made from a variety of semiconductor materials while different semiconductor materials have different energy gap and wavelength of semiconductor material is inversely proportional to the energy gap. The wavelength-energy gap conversion formula (μm)=1.24/. Energy gap (eV). Thus the wavelength of the semiconductor materials changes along with the energy gap, as shown in the following list one:

List one

| | gallium | | |
|---|---|---|---|
| | nitride | | |
| material | (GaN) | In._{0.14}Ga._{0.86}N. | In._{0.24}Ga._{0.76}N. |
| Energy | 3.4 | 3.1 | 2.8 |
| gap | | | |
| (eV) | | | |
| wavelength | 365 | 400 | 445 |
| (μm) | | | |
| color | ultraviolet | Light blue | blue |

In order to make the light emitting device with LED emit other colored light, photoluminescent materials are used to absorb first colored light from the LED and being excited for generating second colored light. The first colored light and the second colored light are mixed to form mixing colored light. For example, phosphor powder can be used. But the colored light excited is radiated from the photoluminescent material so that part of the second colored light is not mixed with the first colored light to be emitted outward. Thus the mixing colored light from the light emitting device is not from complete mixing of the first colored light and the second colored light. This leads to reduced lighting efficiency of the light emitting device.

Thus there is a need to invent a light emitting device with selective reflection function that includes a selective reflection layer allows the first colored light from LED passing through and reflects the second colored light from the excited photoluminescent material so as to enhance the light emitting efficiency.

### SUMMARY OF THE INVENTION

Therefore it is a primary object of the present invention to provide a light emitting device with selective reflection function in which second colored light generated from the excited materials is reflected so as to prevent the second colored light from emitting into the vertical light emitting unit. Thus the light emitting efficiency of the light emitting device is improved.

In order to achieve above object, a light emitting device of the present invention is composed of at least one vertical light emitting unit, at least one selective reflection layer and a phosphor layer. The selective reflection layer is disposed over the vertical light emitting unit and is located on a light output surface of the vertical light emitting unit while the phosphor layer is arranged over the selective reflection layer and is located on a light output surface of the selective reflection layer. The vertical light emitting unit emits first colored light and the selective reflection layer allows the first colored light passing through. The phosphor layer absorbs the first colored light to be excited for generating second colored light. The selective reflection layer reflects the second colored light and the first colored light is mixed with the second colored light to form mixing colored light. The second colored light will not emit into the vertical light emitting unit and the color mixing efficiency of the first colored light with the second colored light is increased. Thus there is no need to use complementary colors. Moreover, besides the vertical light emitting unit can be a general vertical LED, the vertical light emitting unit of the present invention can also be an AC (alternating current)-type LED.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a side view of an embodiment of a light emitting device according to the present invention;

FIG. 1B is a schematic drawing showing optical paths of an embodiment of a light emitting device according to the present invention;

FIG. 2A is a side view of another embodiment of a light emitting device according to the present invention;

FIG. 2B is a schematic drawing showing optical paths of another embodiment of a light emitting device according to the present invention;

FIG. 3 is a side view of a selective reflection layer in an embodiment of the present invention;

FIG. 4A is a side view of a further embodiment of a light emitting device according to the present invention;

FIG. 4B is a schematic drawing showing optical paths of a further embodiment of a light emitting device according to the present invention.

### DETAILED DESCRIPTION OF THE PREFERRED EMBODIMENT

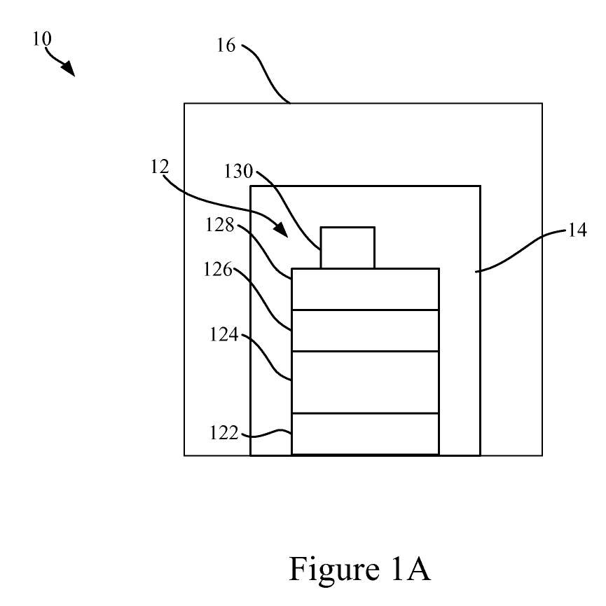

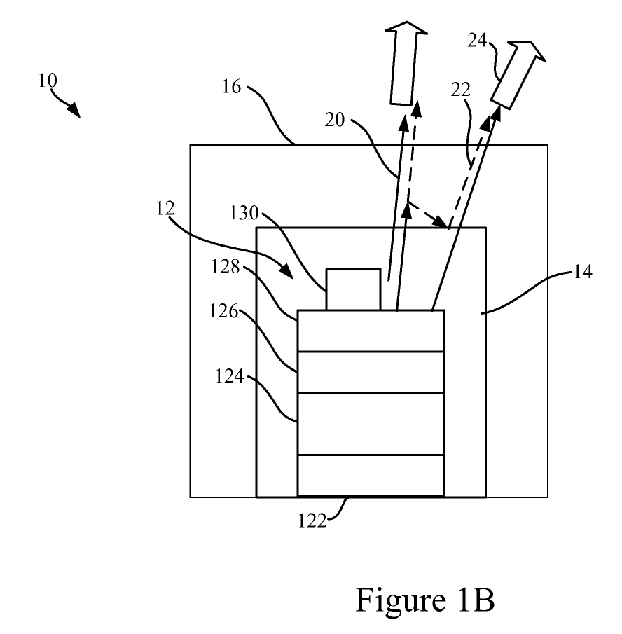

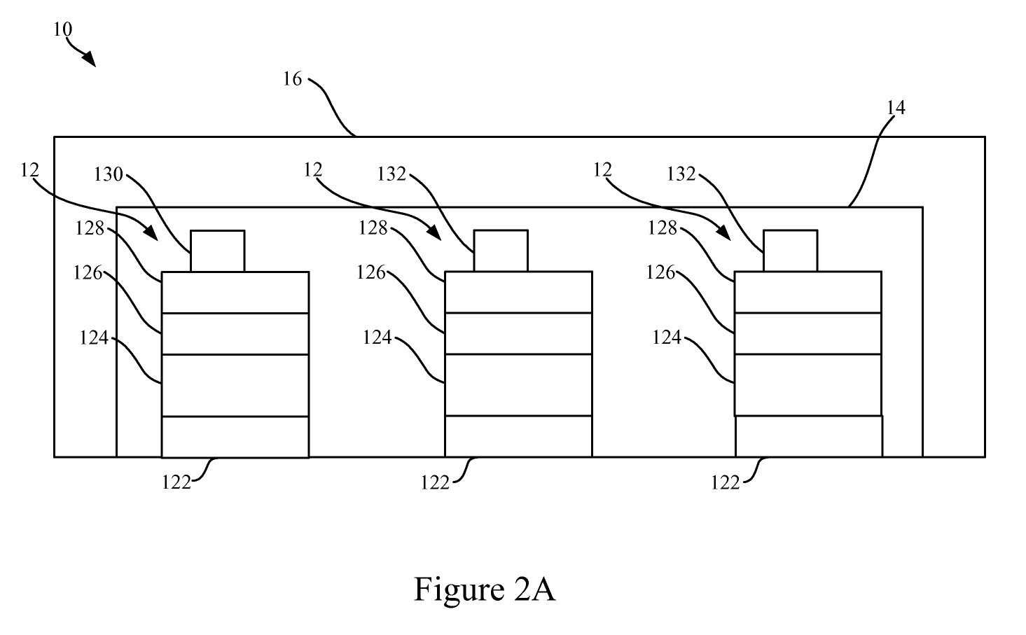

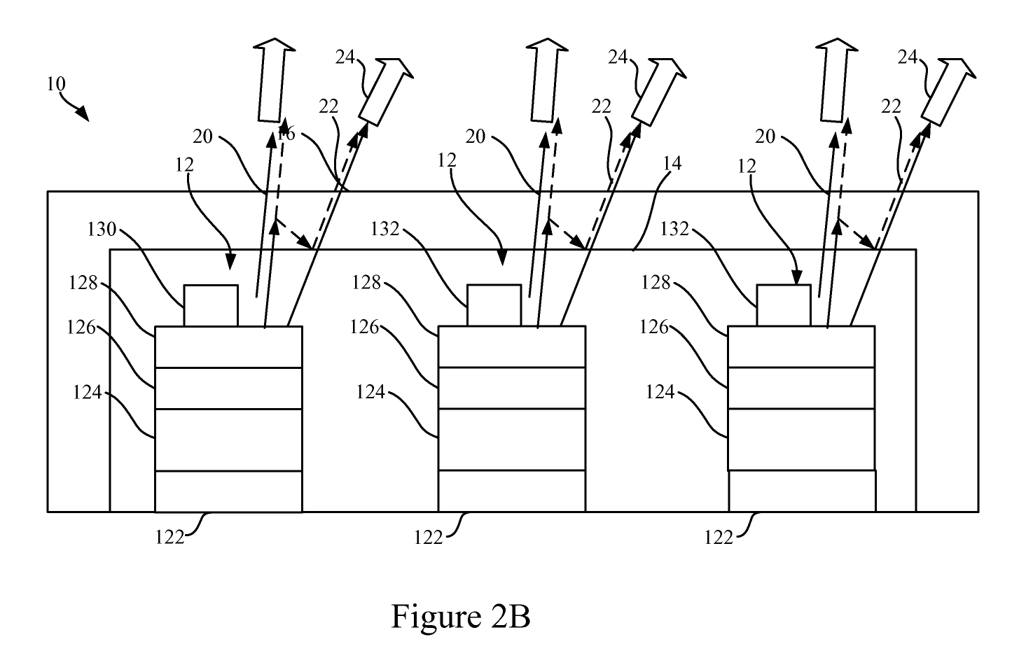

Refer to FIG. 1A, a light emitting device 10 of the present invention includes at least one vertical light emitting unit 12, at least one selective reflection layer 14 and a phosphor layer 16. The selective reflection layer 14 is disposed over the vertical vertical 12 and the phosphor layer 16 is set over the selective reflection layer 14. In this embodiment, the light emitting unit 12 is a general vertical light emitting diode (LED). There is only one vertical light emitting unit 12 in this embodiment but the number of the vertical light emitting unit 12 of the light emitting device 10 is not limited. As shown in FIG. 2A, in another embodiment, the light emitting device 10 includes a plurality of vertical light emitting unit 12.

As shown in FIG. 1B & FIG. 2B, the vertical light emitting unit 12 generates first colored light 20 that passes the selective reflection layer 14. Thus the selective reflection layer 14 will not reflect the first colored light 20. After the first colored light 20 emitting into the phosphor layer 16, the phosphor layer 16 is excited by the first colored light 20 to produce second colored light 22. The first colored light 20 is mixed with the second colored light 22 to form mixing colored light 24. The second colored light 22 is unable to pass through the selective reflection layer 14 so that the selective reflection layer 14 reflects the second colored light 22 and prevents the second colored light 22 from reaching the vertical LED 12. And reduction of the color mixing efficiency of the first colored light 20 with the second colored light 22 is further avoided. Moreover, it's difficult to find mixing colored light 24 in the vertical light emitting unit 12. In this embodiment, the first colored light 20 is blue light and the second colored light 22 is yellow light. Furthermore, the first colored light 20 as well as the second colored light 22 can be modified according to requirements of the mixing colored light 24. That means adjustment of materials of the vertical light emitting unit 12 and materials of the phosphor layer 16. It is learned that the light emitting device 10 of the present invention prevents the second colored light 22 from entering into the vertical light emitting unit 12 so as to improve light emitting efficiency thereof.

Return back to FIG. 1A and FIG. 2A, each vertical light emitting unit 12 comprises a conductive substrate 122, a first semiconductor layer 124, a light emitting layer 126, a second semiconductor layer 128 and an electrode 130. The first semiconductor layer 124 is disposed over the substrate 122 and the light emitting layer 126 is arranged over the first semiconductor layer 124. The second semiconductor layer 128 is set over the light emitting layer 126 and the electrode 130 is disposed over the second semiconductor layer 128. The selective reflection layer 14 is also arranged over the second semiconductor layer 128 while the electrode 130 is covered by the selective reflection layer 14. When the first semiconductor layer 124 is a n-type semiconductor layer, the second semiconductor layer 128 is a p-type semiconductor layer. Once the first semiconductor layer 124 is a p-type semiconductor layer, the second semiconductor layer 128 is a n-type semiconductor layer. Moreover, the light emitting device 10 can be disposed on a bowl-shaped submount. By better focusing effect provided by the bowl-shaped submount, the light emitting efficiency is further enhanced.

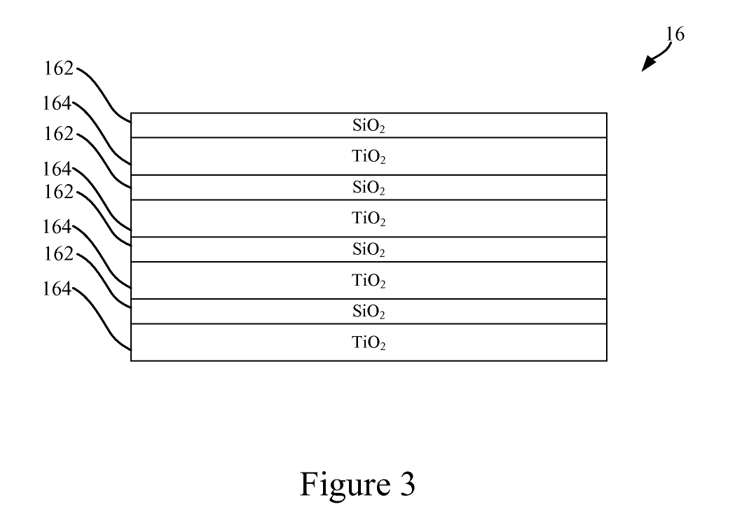

As shown in FIG. 3, the selective reflection layer 14 is Bragg grating whose thickness ranges from 500 Å to 500000 Å (1×10-10 meter). The selective reflection layer 14 includes a plurality of dielectric layers are made from two of the following: silicon dioxide, titanium dioxide, tantalum oxide, zinc oxide, niobium oxide, aluminum nitride, indium nitride, tin nitride and magnesium nitride. In this embodiment, a plurality of first dielectric layers 162 and a plurality of second dielectric layers 164 respectively are made from silicon dioxide and titanium dioxide. The thickness of the first dielectric layer 162 is different from that of the second dielectric layer 164. Thus the selective reflection layer 14 is formed by a plurality of dielectric layers with different thickness.

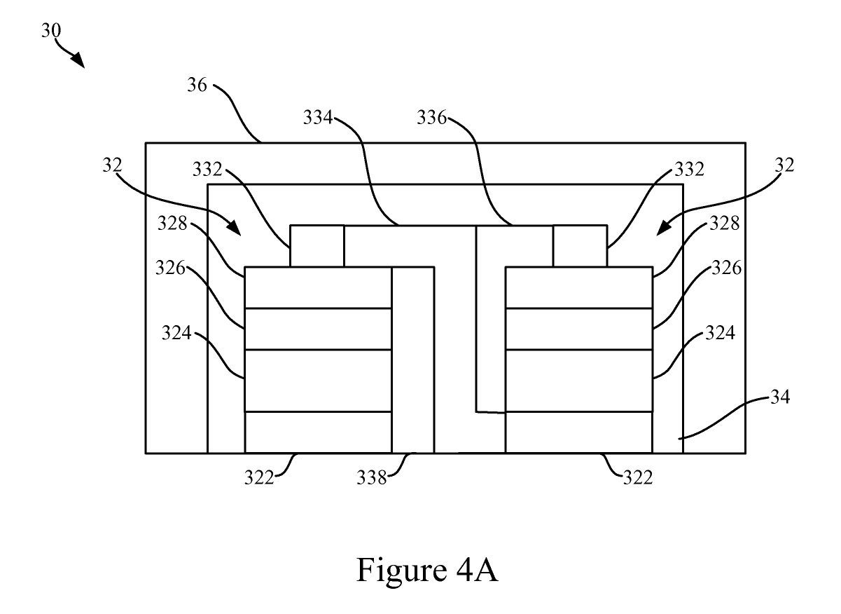

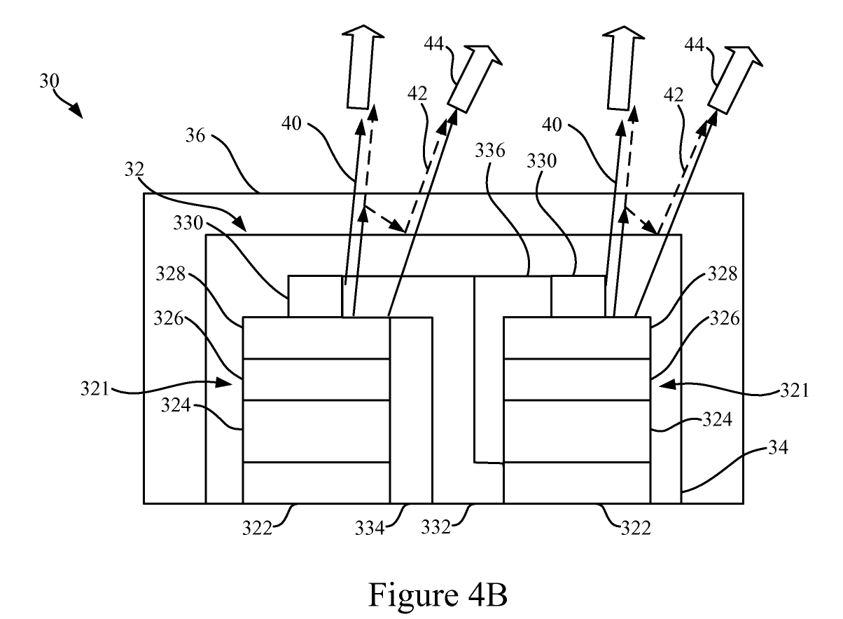

Refer to FIG. 4A, a side view of another embodiment is revealed. A light emitting device 30 comprises at least one light emitting unit 32, at least one selective reflection layer 34 and a phosphor layer 36. The selective reflection layer 34 is disposed over the light emitting unit 32 and the phosphor layer 36 is arranged over the selective reflection layer 34. In this embodiment, the light emitting unit 32 is a AC(alternating current) LED. As shown in FIG. 4B, the light emitting unit 32 generates first colored light 40. The selective reflection layer 34 will not reflect the first colored light 40 because the first colored light passes the selective reflection layer 34. After the first colored light 40 emitting into the phosphor layer 36, the phosphor layer 36 is excited by the first colored light 40 to produce second colored light 42. Then the first colored light 40 and the second colored light 42 are mixed with each other to form mixing colored light 44. The second colored light 42 is unable to pass through the selective reflection layer 34 so that the selective reflection layer 34 reflects the second colored light 42 and prevents the second colored light 42 from entering the light emitting unit 32. And reduction of the color mixing efficiency of the first colored light 40 and the second colored light 42 is further avoided. Moreover, it's difficult to find mixing colored light 44 in the light emitting unit 32. In this embodiment, the first colored light 40 is blue light and the second colored light 42 is yellow light. Furthermore, the first colored light 40 as well as the second colored light 42 can be modified according to requirements of the mixing colored light 24. That means adjustment of materials of the light emitting unit 32 and materials of the phosphor layer 36.

Refer to FIG. 4A again, the light emitting unit 32 includes a plurality of vertical light emitting unit s 321 and each vertical LED 321 having a conductive substrate 322, a first semiconductor layer 324, a light emitting layer 326, a second semiconductor layer 328 and an electrode 330. The first semiconductor layer 324 is arranged over the substrate 322 and the light emitting layer 326 is disposed over the first semiconductor layer 324. The second semiconductor layer 328 is set over the light emitting layer 326 and the electrode 330 is disposed over the second semiconductor layer 328. The selective reflection layer 34 is also disposed over the second semiconductor layer 328 so that the electrode 330 is covered by the selective reflection layer 34. The electrode 330 of one vertical LED 321 is electrically connected with a conductive substrate 322 of an adjacent vertical LED 321 by a transparent electrode 332 so that the conductive substrate 322 of the vertical LED 321 is electrically connected with the electrode 330 of the vertical LED 321. A first insulation layer 334 and a second insulation layer 336 are disposed between the transparent electrode 332 and the vertical LED 321 so that to prevent short circuit occurs between the transparent electrode 332 and the vertical LED 321 on two sides thereof. In this embodiment, each of the vertical LEDs 321 includes only one selective reflection layer 34. But the number of the selective reflection layer 34 is not restricted. In the light emitting device 30, a plurality of selective reflection layers 34 can be disposed over the plurality of the vertical LEDs 321.

When the first semiconductor layer 324 is a n-type semiconductor layer, the second semiconductor layer 328 is a p-type semiconductor layer. If the first semiconductor layer 324 is a p-type semiconductor layer, the second semiconductor layer 328 is a n-type semiconductor layer. Moreover, the substrate 322 can be designed into bowl-shaped so as to make the light emitting device 30 have focusing effect.

In summary, a light emitting device with light selection function of the present invention is applied to general vertical LED or vertical AC-type LED. The selective reflection layer is disposed on general vertical LED or vertical AC LED and the phosphor layer arranged over the selective reflection layer. Said vertical LED emits first color light that excites the phosphor layer and causes the phosphor layer emitting second colored light. The selective reflection layer allows the first colored light from Said vertical LED to pass through but reflects the second colored light from the phosphor layer and prevents the second colored light emitting into the light emitting device. Thereby the light emitting efficiency of the light emitting device is increased.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A light emitting device with selective reflection function comprising:
at least one vertical light emitting unit that emits first colored light,
at least one selective reflection layer disposed over the light emitting unit and located on one light output surface of the light emitting unit while the first colored light passing through the selective reflection layer, and
a phosphor layer arranged over the selective reflection layer for absorbing the first colored light to generate second colored light and the first colored light being mixed with the second colored light to generate mixing colored light; the selective reflection layer reflects the second colored light.

2. The device as claimed in claim 1, wherein the first colored light is blue light.

3. The device as claimed in claim 1, wherein the second colored light is yellow light.

4. The device as claimed in claim 1, wherein thickness of the selective reflection layer ranges from 500 Å (1×10-10 meter) to 500000 Å.

5. The device as claimed in claim 1, wherein the selective reflection layer includes a plurality of dielectric layers.

6. The device as claimed in claim 5, wherein the dielectric layers are made from at least two compounds selected from silicon dioxide, titanium dioxide, tantalum oxide, zinc oxide, niobium oxide, aluminum nitride, indium nitride, tin nitride and magnesium nitride.

7. The device as claimed in claim 5, wherein thickness of each dielectric layer is different from one another.

8. The device as claimed in claim 5, wherein one of the dielectric layers and adjacent dielectric layers are made from different materials.

9. The device as claimed in claim 1, wherein the vertical light emitting unit is a general Light emitting diode(LED) which comprising:
a conductive substrate,
a first semiconductor layer disposed over the conductive substrate,
a light emitting layer arranged over the first semiconductor layer and emitting the first colored light,
a second semiconductor layer disposed over the light emitting layer, and
an electrode arranged at the second semiconductor layer,
wherein the selective reflection layer is disposed over the second semiconductor layer.

10. The device as claimed in claim 1, wherein the vertical light emitting unit is an alternating current light emitting diode(AC LED) having a plurality of vertical LED which are connect according to electric property and are powered by an AC power to emit a first colored light.

11. The device as claimed is claim 10, wherein the light emitting device further includes a submount disposed under the vertical light emitting unit.

12. The device as claimed is claim 10, wherein the first colored light is blue light.

13. The device as claimed is claim 10, wherein the second colored light is yellow light.

14. The device as claimed is claim 10, wherein thickness of the selective reflection layer ranges from 500 Å (1×10-10 meter) to 500000 Å.

15. The device as claimed is claim 10, wherein the selective reflection layer includes a plurality of dielectric layers.

16. The device as claimed is claim 15, wherein the dielectric layers are made from at least two compounds selected from silicon dioxide, titanium dioxide, tantalum oxide, zinc oxide, niobium oxide, aluminum nitride, indium nitride, tin nitride and magnesium nitride.

17. The device as claimed is claim 15, wherein thickness of each dielectric layer is different from one another.

18. The device as claimed is claim 15, wherein one of the dielectric layers and adjacent dielectric layers are made from different materials.

19. The device as claimed is claim 10, wherein the vertical light emitting unit comprising:
a conductive substrate,
a first semiconductor layer disposed over the conductive substrate,
a light emitting layer arranged over the first semiconductor layer and emitting the first colored light,
a second semiconductor layer disposed over the light emitting layer, and
an electrode arranged at the second semiconductor layer,
Wherein an insulation layer is respectively disposed between the plurality of vertical light emitting unit while an electrode of an vertical light emitting unit of a plurality of vertical light emitting unit s is electrically connected with a conductive substrate of an adjacent vertical light emitting unit; the selective reflection layer is disposed over the second semiconductor layer.

20. The device as claimed in claim 19, wherein the selective reflection layers are respectively disposed on the vertical light emitting units and respectively located on a light output surface of each vertical light emitting unit.
